(19) United States
(12) Patent Application Publication
(10) Pub. No.: US 2013/0242504 A1
(43) Pub. Date: Sep. 19, 2013

(54) COOLING AN ELECTRONIC ASSEMBLY USING POSITION VARIABLE FLOW RESTRICTORS

(71) Applicants: Andrew C. CARTES, Cypress, TX (US); Sarah N. Anthony, Houston, TX (US)

(72) Inventors: Andrew C. CARTES, Cypress, TX (US); Sarah N. Anthony, Houston, TX (US)

(21) Appl. No.: 13/423,916

(22) Filed: Mar. 19, 2012

(51) Int. Cl. G06F 1/20; H05K 7/20; G05D 23/19

(52) U.S. Cl. 361/679.49; 165/296; 165/247; 165/80.3; 361/691; 361/679.46

(57) ABSTRACT

A plenum provides cooled air to an inlet of an enclosure. An electronics assembly within the enclosure includes temperature sensors. Each of a plurality of position variable flow restrictors is positioned to control flow of the cooled air to a portion of the electronics assembly. A controller individually positions each flow restrictor based on temperature measurements provided by the temperature sensors associated with the portion of the electronics assembly for which cooled air is provided via the flow restrictor.

### BACKGROUND

Computer systems or servers, at a datacenter or other location, may be rack-mounted. Each rack (e.g., Electronics Industry Association standard racks) may house a number of computer systems or servers. The components of each computer system may dissipate significant amounts of heat during operation. Each computer system is typically cooled by fans that move cooling fluid, e.g., air, conditioned air, etc., across the heat dissipating components.

### BRIEF DESCRIPTION OF THE DRAWINGS

For a detailed description of various examples of the invention, reference will now be made to the accompanying drawings in which:

FIG. 1 shows a schematic level diagram for a system for cooling a server that employs louvers in accordance with principles disclosed herein;

FIG. 2 shows a block diagram for a system for cooling a server that employs louvers in accordance with principles disclosed herein;

FIG. 3 shows a flow diagram for a method for cooling a server using louvers to direct airflow in accordance with principles disclosed herein; and

FIG. 4 shows a flow diagram for a method for cooling a server using louvers to direct airflow in accordance with various principles disclosed herein.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect, direct, optical or wireless electrical connection. Thus, if a first device couples to a second device, that connection may be through a direct electrical connection, through an indirect electrical connection via other devices and connections, through an optical electrical connection, or through a wireless electrical connection. The recitation “based on” is intended to mean “based at least in part on.” Therefore, if X is based on Y, X may be based on Y and any number of additional factors.

### DETAILED DESCRIPTION

The following discussion is directed to various implementations of a cooling system that employs individually positionable louvers to direct cooling fluid to an electronic assembly. The principles disclosed have broad application, and the discussion of any implementation is meant only to illustrate that implementation, and not intended to intimate that the scope of the disclosure, including the claims, is limited to that implementation.

Servers and other electronic assemblies are generally cooled using fans to move cool air across heat dissipating components. Data centers supporting a large number of servers can employ thousands of fans. Such systems are subject to a number of disadvantages. For example, fan inefficiencies accumulate as the number of fans increase, and fans always consume some power because they must be run at at least a nominal rate to prevent leakage current even when no cooling is needed.

The systems disclosed herein employ flow restrictors, such as louvers, to control airflow across server components. The flow restrictors can directly replace fans and be operated by a fan controller, and unlike fans, the flow restrictors do not present cumulative inefficiencies. Further, use of flow restrictors reduces system power consumption because the flow restrictors consume power only when changing position, and the power consumed is not dependent on the rate of airflow as with fans. Additionally, in some implementations, the flow restrictors require less space than fans.

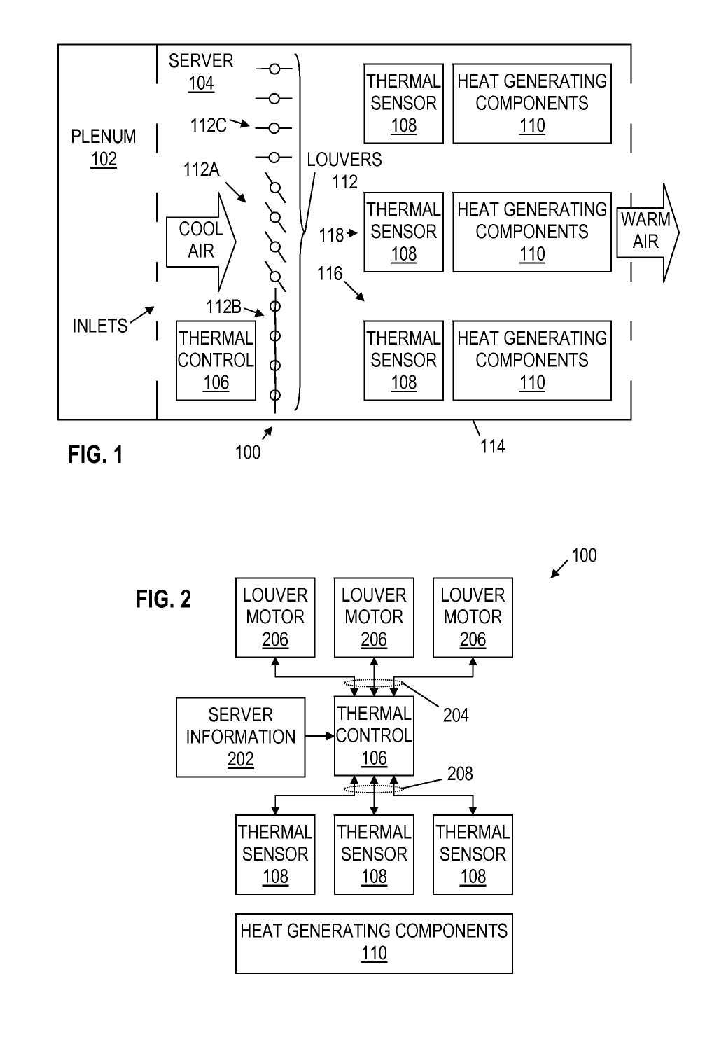

FIG. 1 shows a schematic level diagram for a system for cooling a server 104 that employs louvers 112 in accordance with principles disclosed herein. The system 100 includes a plenum 102 and the server 104. The plenum 102 provides pressurized cool air to an air inlet of the server 104. For example, the temperature of the cool air provided via the plenum 102 may be lower than the temperature of the air flowing out of the server 104. The pressurized cool air provided through the plenum 102 may be generated by a central computer room air conditioning system (not shown). Providing pressurized cool air from a central source improves overall cooling system efficiency because the larger fan at the air source moves air more efficiently than small fans disposed in the server 104.

The server 104 includes an enclosure 114, a plurality of louvers 112 or other airflow restrictors, a thermal controller 106, thermal sensors 108, and heat generating components 110. The louvers 112 are slats, blades, fins, or the like that change position about an axis to vary the size of an air passage and/or the direction of airflow. The heat generating components may be, for example, electronic components, such as processor(s), memories, and/or various other integrated circuits, semiconductor devices, etc. that dissipate heat while operating.

The thermal sensors 108 are distributed about the interior of the server 104 to provide measurement of temperatures across different regions of the interior of the server 104. The thermal sensors 108 may include any type of suitable temperature sensor, and may be integrated into or separate from any electronic component included in the server 104. For example, a temperature sensor 108 may integrated with a processor and/or provided as a discrete device. While three temperature sensors 108 are illustrated in the server 104 as a matter of convenience, in practice, the server 104 may include two or more thermal sensors 108.

The thermal sensors 108 are coupled to a thermal controller 106. The thermal controller 106 controls the positioning of the louvers 112 in accordance with the temperature measurements provided by the thermal sensors 108 and/or other relevant information provided by the server 104. The thermal controller 106 receives temperature measurements from the thermal sensors 108, and determines from the measurements a level of cooling needed for each of multiple regions of the server 104, where the regions correspond to areas having a temperature measured by one or more of the thermal sensors 108. For example, one thermal region of the server 104 may be dedicated to a processor, and another thermal region of the server 104 may be dedicated to memory, etc.

The thermal controller 106 may include a processor that executes instructions retrieved from a computer-readable medium. Suitable processors may include, for example, one or more general-purpose microprocessors, digital signal processors, microcontrollers, or other devices capable of executing instructions retrieved from a computer-readable storage medium. Processor architectures generally include execution units (e.g., fixed point, floating point, integer, etc.), storage (e.g., registers, memory, etc.), instruction decoding, peripherals (e.g., interrupt controllers, timers, direct memory access controllers, etc.), input/output systems (e.g., serial ports, parallel ports, etc.) and various other components and sub-systems. In some implementations, the thermal controller 106 may be implemented via a server management system, such as an Integrated Lights-Out Baseboard Management Computer.

A processor may store data in and execute instructions retrieved from a non-transitory computer-readable storage medium. A non-transitory computer-readable storage medium may include volatile storage such as random access memory, non-volatile storage (e.g., a hard drive, an optical storage device (e.g., CD or DVD), FLASH storage, read-only-memory), or combinations thereof. In some implementations, a storage medium may be local to the processor. In other implementations, storage may be remote from the processor accessed via a network.

The thermal controller 106 generates signals that control the positions of the louvers 112. Some implementations of the thermal controller 106 control the position of each louver 112 individually. The thermal controller 106 may generate signals that can be used to control the rotation rate of fans, i.e., the thermal controller 106 may be a fan controller. For example, the thermal controller 106 may generate pulse width modulated (PWM) signals, wherein the duty cycle of each signal corresponds to the rotation rate of a fan used to cool a portion of the server. The louvers 112 may replace fans in the server 104, and the louvers 112 may apply the PWM fan control signals generated by the thermal controller 106 to determine louver position. For example, the degree to which a louver 112 is open may correspond to the duty cycle of the PWM fan control signal. Accordingly, in some implementations, a louver 112 may move to the closed position 112B (blocking airflow therethrough) based on a 0% duty cycle PWM fan control signal and move to the fully open position 112C based on a 100% duty cycle PWM fan control signal.

The thermal controller 106 may individually position the louvers 112 to provide a needed level of flow of cooled airflow to each region of the server 104, and may also position the louvers 106 to direct cooled airflow within the server 104. For example, the positioning of the louvers 112A may direct cooled airflow to region 116 of the server 104 rather than region 118.

FIG. 2 shows a block diagram for the system 100 for cooling a server 104 that employs louvers 112 in accordance with principles disclosed herein. As explained above, the thermal controller 106 receives temperature measurements 208 from the thermal sensors 108 which are distributed within the server 104. The thermal controller 106 employs the temperature measurements 208 to determine what level of cooling is needed within the server 104 and positions the louvers 112 accordingly.

The thermal controller 106 also receives server information 202 from various components within the server 104. The server information 202 includes non-temperature measurement information that is indicative of a need for cooling in a particular region of the server 104. For example, the server information 202 may include clock rate information provided by a processor of the server 104, bus utilization information, power consumption information, etc. that may be indicative of the level of cooling needed in a region of the server 104. The thermal controller 106 may position the louvers 112 based on the server information 202.

Based on the temperature measurements 208 provided by the thermal sensors 108 and/or the server information 202 indicative of needed level, degree, or amount of cooling, the thermal controller 106 generates the control signals 204. The control signals 204 control louver motors 206 that move the louvers 112. The louver motors 206 may be any type of actuators that can change the position of the louvers 112. For example, a louver motor 206 may be a stepper motor used in conjunction with a shaft position encoder to position a louver 112 and feedback louver position information to the thermal controller 106. In some implementations, each louver 112 is controlled by a separate and distinct louver motor 206. As explained above, the thermal controller 106 may be a fan controller, and the control signals 204 maybe fan speed control signals, such as PWM signals having a duty cycle proportional to fan speed. The louver motors 206 and/or circuitry associated therewith may determine a requested louver position based on the fan control signals and/or convert the fan control signals into signals that move the louvers 112 into a requested position.

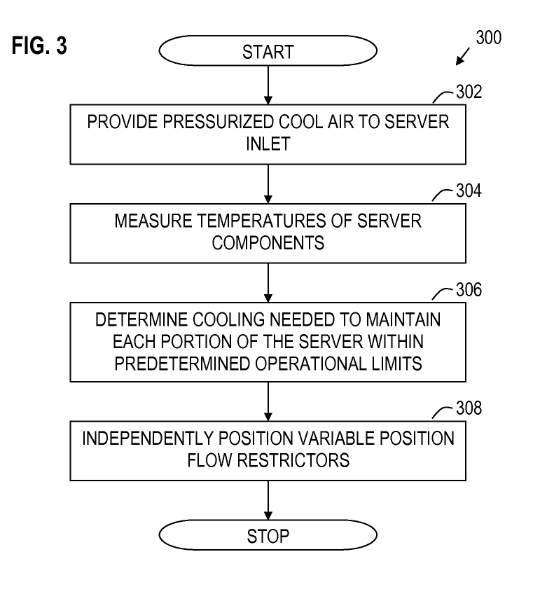

FIG. 3 shows a flow diagram for a method 300 for cooling a server using louvers 112 to direct airflow in accordance with principles disclosed herein. Though depicted sequentially as a matter of convenience, at least some of the actions shown can be performed in a different order and/or performed in parallel. Additionally, some implementations may perform only some of the actions shown. At least some of the operations of the method 300 can be performed by processor(s) executing instructions retrieved from a computer-readable medium.

In block 302, the server 104 is operating. Components of the server 104 are dissipating heat, and cooling is provided to maintain the components of the server 104 within a predetermined operating temperature range. The inlets of the server 104 are coupled to the plenum 102. The plenum 102 provides pressurized cooled air to the server 104. The cooled air may be provided from a central source, such as a computer room air conditioner.

In block 304, the temperature sensors 108 distributed about the interior of the server 104 measure the temperatures of components and/or air within the server.

In block 306, based on the temperature measurements provided by the temperature sensors 108, the thermal controller 106 determines a level of cooling need to maintain each portion of the server 104, where the portions of the server are associated the distributed temperature sensors 108, within the predetermined operating temperature limits. For example, portions of the server 104 having a temperature above an upper operating temperature limit may require an increase in flow of cooled air, and portions of the server 104 having a temperature below a lower operating temperature limit may require a reduction in flow of cooled air.

In block 308, the thermal controller 106 positions the variable position flow restrictors (e.g., the louvers 112) within the server 104 to direct cooled air provided from the plenum 102 to the portions of the server 104 where cooling is needed. For example, the thermal controller 106 may adjust the positions of some of the flow restrictors 112 to increase the flow of cooled air to a portion of the server 104, and may adjust the positions of other of the flow restrictors 112 to decrease the flow of cooled air to a different portion of the server 104.

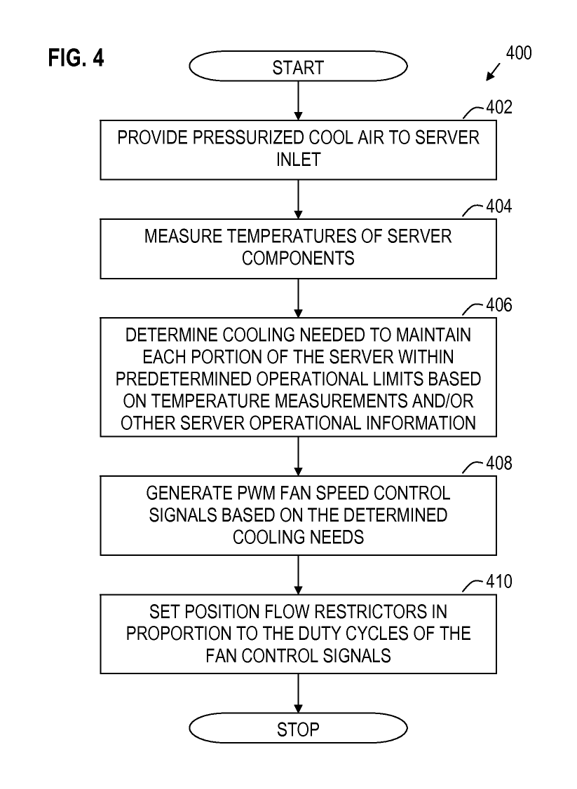

FIG. 4 shows a flow diagram for a method 400 for cooling a server using louvers to direct airflow in accordance with principles disclosed herein. Though depicted sequentially as a matter of convenience, at least some of the actions shown can be performed in a different order and/or performed in parallel. Additionally, some implementations may perform only some of the actions shown. At least some of the operations of the method 400 can be performed by processor(s) executing instructions retrieved from a computer-readable medium.

In block 402, the server 104 is operating. Components of the server 104 are dissipating heat, and cooling is provided to maintain the components of the server 104 within a predetermined operating temperature range. The inlets of the server 104 are coupled to the plenum 102. The plenum 102 provides pressurized cooled air to the server 104. The cooled air may be provided from a central source, such as a computer room air conditioner.

In block 404, the temperature sensors 108 distributed about the interior of the server 104 measure the temperatures of components and/or air within the server.

In block 406, based on the temperature measurements provided by the temperature sensors 108, the thermal controller 106 determines a level of cooling need to maintain each portion of the server 104 within the predetermined operating temperature limits. The thermal controller 106 determines the level of cooling needed by each portion of the server 104 based on temperature measurements provided by the temperature sensors 108 and/or based on other server operation information (e.g., clock rates, bus utilization, etc.) indicative of a level of cooling needed by a portion of the server 104.

In block 408, the thermal controller 106 generates control signals to adjust the cooling provided to portions of the server 104. Some implementations of the thermal controller 106 are fan controllers that generate PWM fan speed control signals. The thermal controller generates the control signals based on the determined cooling needs of each region or portion of the server 104.

In block 410, the positions of the flow restrictors 112 within the server 104 are set in accordance with the control signals generated by the thermal controller 106. The flow restrictors (e.g., the louvers 112) are set to direct cooled air provided from the plenum 102 to the portions of the server 104 where cooling is needed. For example, the thermal controller 106 may adjust the positions of some of the flow restrictors 112 to increase the flow of cooled air to a portion of the server 104, and may adjust the positions of other of the flow restrictors 112 to decrease the flow of cooled air to a different portion of the server 104. In some implementations, each flow restrictor 112 is opened in proportion to the duty cycle of the PWM control signal associated with the flow restrictor 112 (e.g., 100% duty cycle—fully open, 0% duty cycle—fully closed).

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A system, comprising:
an enclosure;
an electronics assembly disposed within the enclosure, the electronics assembly comprising a plurality of temperature sensors;
a plenum to direct cooled air coupled to an inlet of the enclosure;
a plurality of position variable flow restrictors, each flow restrictor positioned to control flow of the cooled air to a portion of the electronics assembly; and
a controller to individually position each flow restrictor based on measurements provided by the temperature sensors associated with the portion of the electronics assembly for which cooled air is provided via the flow restrictor.

2. The system of claim 1, wherein the controller is a fan speed controller, and each flow restrictor is to vary a degree of restriction based on a fan speed signal provided by the fan speed controller.

3. The system of claim 2, wherein the fan speed signal is a pulse width modulated signal indicative of fan speed, and the flow restrictors are to vary angular position based on the pulse width modulated signal.

4. The system of claim 1, wherein the flow restrictors are position variable louvers.

5. The system of claim 1, wherein the controller is further to position each flow restrictor based on at least one of a measurement of power consumed the electronics assembly, clock rate information provided by the electronics assembly, and bus utilization information provided by the electronics assembly.

6. The system of claim 1, wherein the controller is further to angularly position a given flow restrictor to divert cooled air from a cooler portion of the electronics assembly downstream of the given flow restrictor to a warmer portion of the electronics assembly downstream of the given flow restrictor.

7. A method, comprising:
directing pressurized, cooled air to an inlet of a server enclosure;
measuring temperatures of a plurality of components of a server board disposed within the enclosure;
determining an amount of cooling needed to maintain each of the plurality of components of the server board within predetermined operation limits based on the measured temperatures;
positioning, independently, a plurality of variable position flow restrictors associated with the server board to provide the pressurized, cooled air to the components of the server board responsive to the determining.

8. The method of claim 7, further comprising generating fan speed control signals responsive to the determining; wherein the positioning of each flow restrictor is based on one of the fan speed control signals.

9. The method of claim 8, wherein the fan speed control signals are pulse width modulated signals and the positioning of each flow restrictor is based on a duty cycle of one of the fan speed control signals.

10. The method of claim 7, wherein the flow restrictors are louvers, and the positioning comprises setting an angle of each louver.

11. The method of claim 7, wherein the determining is further based on at least one of a measurement of power consumed by the server board, clock rate information provided by the server board, and bus utilization information provided by the server board.

12. The method of claim 7, wherein the positioning further comprises angularly positioning a given flow restrictor to divert cooled air directed to a cooler portion of the server board downstream of the given flow restrictor to a warmer portion of the server board downstream of the given flow restrictor.

13. An apparatus, comprising:
a plurality of servers disposed within an enclosure; and
a plenum to channel cooled air to each server, each server comprising:
a thermal control system, comprising:
a plurality of thermal sensors;
a plurality of individually angularly positionable louvers; and
a thermal controller;
wherein the thermal controller is to:
determine a level of flow of cooled air to provide each of a plurality of regions of the server based on measurements provided by the thermal sensors; and
adjust a position of at least one louver based on the determined level of flow of cool air to be provided to a region of the server associated with the louver.

14. The apparatus of claim 13, wherein the thermal controller is a fan controller to produce a pulse width modulated fan speed control signal, and each louver sets an angular position based on a duty cycle of the pulse width modulated fan speed control signal.

15. The apparatus of claim 13, wherein the thermal controller is to angularly position each louver to divert cooled air from a cooler portion of the server downstream of the flow restrictor to a warmer portion of the server downstream of the flow restrictor.

16. The apparatus of claim 13, wherein the thermal controller is to position each louver based on at least one of a measurement of power consumed the server, clock rate information provided by the a processor of the server, and bus utilization information provided by the server.
